(19) United States
(12) Patent Application Publication
(10) Pub. No.: US 2020/0084914 A1
(43) Pub. Date: Mar. 12, 2020

(54) MEMORY SYSTEM AND STORAGE SYSTEM

(71) Applicant: TOSHIBA MEMORY CORPORATION, Tokyo (JP)

(72) Inventors: Kengo KUMAGAI, Yokohama Kanagawa (JP); Daigo TANUMA, Kunitachi Tokyo (JP)

(21) Appl. No.: 16/413,494

(22) Filed: May 15, 2019

(30) Foreign Application Priority Data
Sep. 12, 2018 (JP) 2018-170552

(51) Int. Cl. H05K 7/20; H01L 23/367; H01L 23/31; H05K 1/18; H05K 5/06; H05K 1/02

(52) U.S. Cl. CPC H05K 7/20236; H01L 23/367; H01L 23/3107; H05K 1/181; H05K 5/065; H05K 2201/10159; H05K 7/20772; H05K 2201/10522; H05K 2201/10545; H05K 2201/066; H05K 1/0203

(57) ABSTRACT

A memory system includes a substrate extending in a first direction and including first and second portions that are arranged along a line in the first direction, terminals disposed on the first portion, electronic components mounted on the second portion and including a nonvolatile memory and a controller configured to control the nonvolatile memory, and an encapsulating member that encapsulates the second portion and the electronic components.

### CROSS-REFERENCE TO RELATED APPLICATIONS

This application is based upon and claims the benefit of priority from Japanese Patent Application No. 2018-170552, filed Sep. 12, 2018, the entire contents of which are incorporated herein by reference.

### FIELD

Embodiments described herein relate generally to a memory system and a storage system.

### BACKGROUND

A memory system includes a nonvolatile memory and a controller to control the nonvolatile memory. Generally, reliability of the nonvolatile memory at a high temperature is degraded. For this reason, the nonvolatile memory is cooled by various methods.

When a memory system is liquid-cooled, for example, protection of the memory system is performed with a film or a case or an insulating liquid. Consequently, liquid cooling of the memory system is likely to increase the cost.

### DESCRIPTION OF THE DRAWINGS

FIG. 1 is a block diagram schematically illustrating a configuration of a server system according to a first embodiment.

FIG. 2 is a cross-sectional view of a part of the server system according to the first embodiment.

FIG. 3 is a cross-sectional view of a solid state drive (SSD) according to the first embodiment.

FIG. 4 is a cross-sectional view of the SSD according to the first embodiment, taken along line F4-F4 in FIG. 3.

FIG. 5 is a perspective view of the SSD according to the first embodiment.

FIG. 6 is a cross-sectional view of an SSD according to a second embodiment.

FIG. 7 is a cross-sectional view of a part of a server system according to a third embodiment.

### DETAILED DESCRIPTION

In general, according to one embodiment, a memory system includes a substrate extending in a first direction and including first and second portions that are arranged along a line in the first direction, terminals disposed on the first portion, electronic components mounted on the second portion and including a nonvolatile memory and a controller configured to control the nonvolatile memory, and an encapsulating member that encapsulates the second portion and the electronic components.

Electronic devices and semiconductor storage devices according to embodiments will be described in detail below with reference to the accompanying drawings. It is noted that these embodiments do not limit the scope of the present disclosure.

In this specification, components of the embodiments or descriptions of the components may be each referred to by various expressions. The components and their descriptions are not limited by the expressions used in this specification. The components may be referred to names that are different from the ones used in this specification. The components may be described using expressions different from the expressions used in this specification.

### First Embodiment

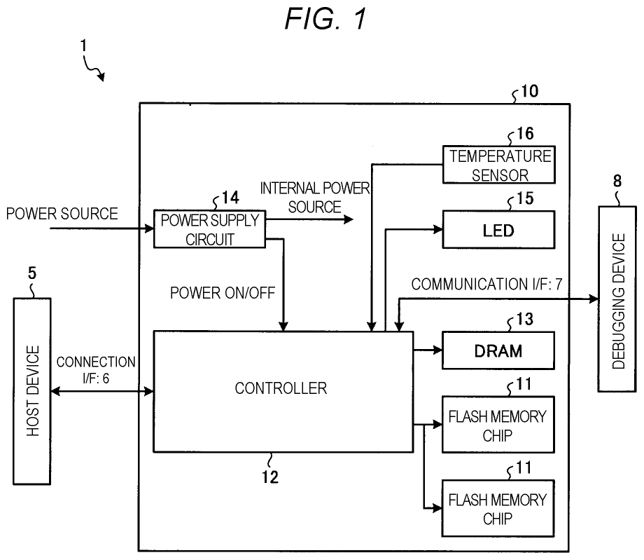

A first embodiment will now be described with reference to FIGS. 1 to 5. FIG. 1 is a block diagram schematically illustrating a configuration of a server system 1 according to the first embodiment. The server system 1 includes a host device (hereinafter referred to as host) 5 and plural solid state drives (SSDs) 10. In FIG. 1, only one of the plural SSDs 10 is illustrated as a representative.

The server system 1 is an example of the storage system and may also be referred to as, for example, a storage device, an electronic device, and a device. It is noted that the storage system is not limited to the server system 1 but may be other devices such as a network attached storage (NAS).

The SSD 10 is an example of the memory system and may be also referred to as, for example, a semiconductor storage device, an electronic device, a device, and a component. It is noted that the memory system is not limited to the SSD 10 but may be other devices such as a hybrid hard disk drive abbreviated as hybrid HDD.

The SSD 10 is connected to the host 5 with a connection interface (I/F) 6. The SSD 10 is used as, for example, an auxiliary storage device for the host 5. The connection interface 6 conforms to the requirements of M.2, Serial Advanced Technology Attachment (SATA), mSATA, Peripheral Component Interconnect Express (PCI Express abbreviated as PCIe), Universal Serial Bus (USB), or Serial Attached SCSI (SAS).

The host 5 is, for example, a main body of the server system 1 and includes a CPU and a motherboard. It is noted that the host 5 is not limited to this example but may be a CPU of a personal computer, a tablet, a smartphone, a mobile phone, or an image capturing device such as a still camera or a video camera.

With a communication interface (I/F) 7 such as an RS232C interface (RS232C I/F), the SSD 10 performs data transmission and reception to and from other devices such as a debugging device 8.

The SSD 10 includes plural flash memory chips 11, a controller 12, a dynamic random access memory (DRAM) 13, a power supply circuit 14, an LED 15, and a temperature sensor 16.

The flash memory chips 11 are an example of a nonvolatile memory and may also be referred to as nonvolatile semiconductor storage elements, electronic components, storage elements, semiconductor elements, storages, elements, and components. The controller 12 may also be referred to as a drive control circuit, an electronic component, a control unit, an element, and a component.

The flash memory chips 11 are, for example, NAND flash memory chips. Alternatively, the flash memory chips 11 may be other kinds of flash memory chips. The DRAM 13 is a volatile memory and may also be referred to as a volatile semiconductor storage element, an electronic component, a storage element, a semiconductor element, a storage unit, an element, and a component. The DRAM 13 stores data at a higher speed than the flash memory chips 11. The LED 15 is used for display of a state of the SSD 10. The temperature sensor 16 detects a temperature inside of the SSD 10.

The controller 12 is, for example, a System-on-a-Chip (SoC). Alternatively, the controller 12 may be other kinds of integrated circuits (ICs) or circuits. The controller 12 controls, for example, the flash memory chips 11, the DRAM 13, the power supply circuit 14, the LED 15, and the temperature sensor 16.

The power supply circuit 14 generates plurality of different internal direct-current (DC) power-supply voltages from an external DC power source that is supplied from a power supply circuit of the host 5. The power supply circuit 14 supplies the internal DC power-supply voltages to the respective circuits in the SSD 10. The power supply circuit 14 detects a startup of the external power source, generates a power-on reset signal, and supplies the power-on reset signal to the controller 12.

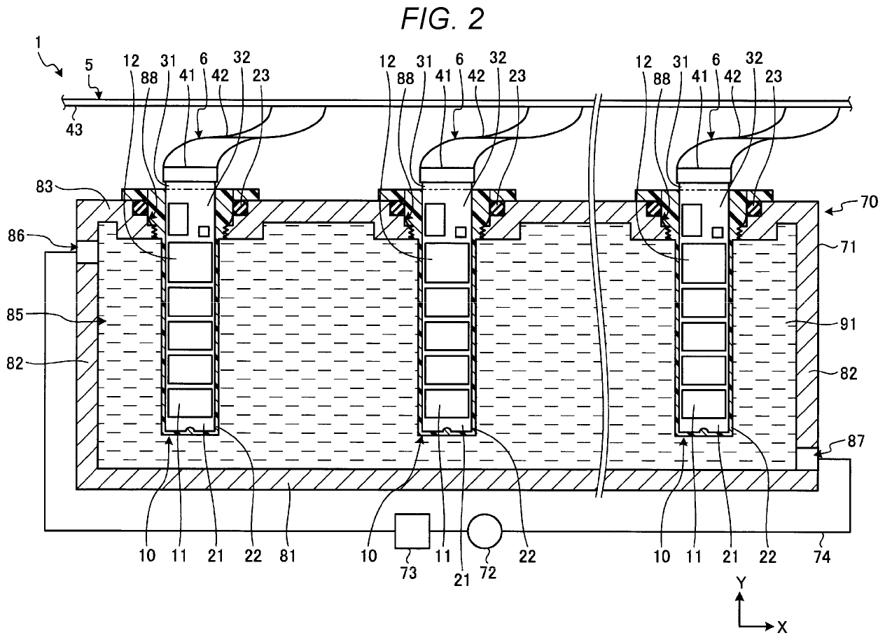

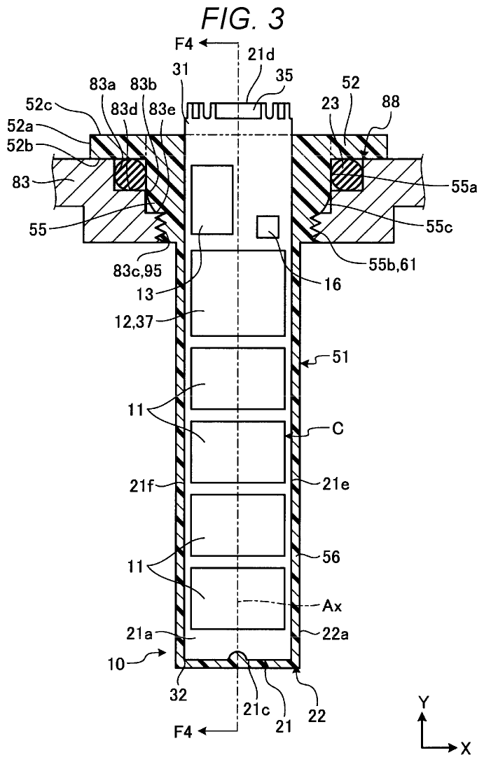

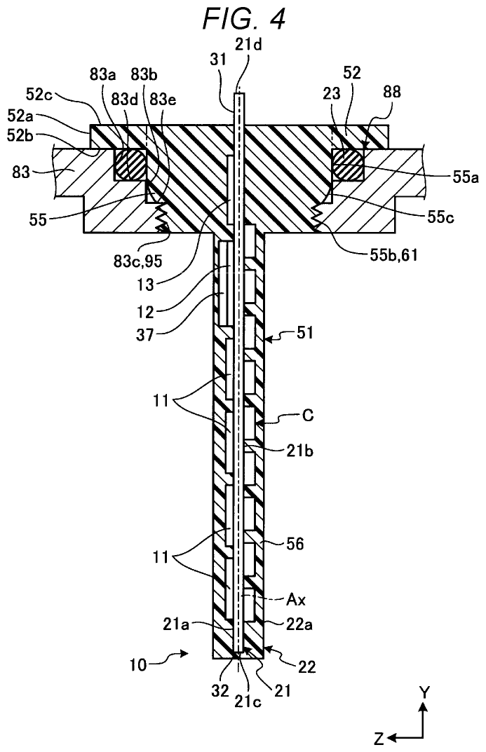

FIG. 2 is a cross-sectional view of a part of the server system 1 according to the first embodiment, schematically illustrating a configuration of the part. FIG. 3 is a cross-sectional view of the SSD 10 according to the first embodiment, schematically illustrating a configuration of the SSD 10. FIG. 4 is a cross-sectional view of the SSD 10 according to the first embodiment, taken along line F4-F4 in FIG. 3, and schematically illustrating a configuration of the SSD 10. The SSD 10 further includes a first substrate 21, an encapsulating member 22, and a gasket 23.

In this specification, the X-axis, the Y-axis, and the Z-axis are defined as illustrated in the drawings. The X-axis, the Y-axis, and the Z-axis are orthogonal to one another. The X-axis extends along a width of the first substrate 21. The Y-axis extends along a length of the first substrate 21. The Z-axis extends along a thickness of the first substrate 21.

As illustrated in FIGS. 3 and 4, the first substrate 21 is, for example, a printed circuit board (PCB). It is noted that the first substrate 21 is not limited to this example but may be other kinds of substrates such as a flexible printed circuit board (FPC). The first substrate 21 has a substantially rectangular plate shape extending in a negative direction of the Y-axis (a direction reverse to the arrow of the Y-axis). The negative direction of the Y-axis is an example of the first direction. The first substrate 21 includes a first mounting surface 21a, a second mounting surface 21b, a first edge 21c, a second edge 21d, a third edge 21e, and a fourth edge 21f.

As illustrated in FIG. 4, the first mounting surface 21a and the second mounting surface 21b are substantially flat surfaces in the X-Y plane. The first mounting surface 21a faces a positive direction of the Z-axis (i.e., a direction indicated by the arrow of the Z-axis). The second mounting surface 21b is on an opposite side of the first mounting surface 21a and faces a negative direction of the Z-axis (i.e., a direction reverse to the direction indicated by the arrow of the Z-axis).

On the first mounting surface 21a and the second mounting surface 21b, plural electronic components C including the plural flash memory chips 11, the controller 12, the DRAM 13, the temperature sensor 16, the power supply circuit 14, and the LED 15, which are illustrated in FIG. 1, are mounted. Alternatively, the plural electronic components C may be mounted on only one of the first mounting surface 21a and the second mounting surface 21b.

As illustrated in FIG. 3, the first edge 21c and the second edge 21d extend in the X-axis direction. The first edge 21c is on an end of the first substrate 21 in the negative direction of the Y-axis and faces the negative direction of the Y-axis. The second edge 21d is on an opposite side of the first edge 21c and faces a positive direction of the Y-axis (i.e., a direction indicated by the arrow of the Y-axis).

The third edge 21e and the fourth edge 21f extend in the Y-axis direction. The third edge 21e is on an end of the first substrate 21 in a positive direction of the X-axis (i.e., a direction indicated by the arrow of the X-axis) and faces the positive direction of the X-axis. The fourth edge 21f is on an opposite side of the third edge 21e and faces a negative direction of the X-axis (i.e., a direction reverse to the direction indicated by the arrow of the X-axis). Each of the third edge 21e and the fourth edge 21f, which are long sides, is longer than each of the first edge 21c and the second edge 21d, which are short sides.

The first substrate 21 further includes a first portion 31 and a second portion 32. The first portion 31 may also be referred to as, for example, an exposed portion or a connector. The second portion 32 may also be referred to as, for example, an elongated portion, a mounting portion, and a package portion. In FIGS. 2 and 3, the first portion 31 and the second portion 32 are separated by the double chain lines.

The first portion 31 and the second portion 32 are arranged in-line in the negative direction of the Y-axis. The first portion 31 includes the second edge 21d, part of the third edge 21e, and part of the fourth edge 21f of the first substrate 21. The second portion 32 extends in the negative direction of the Y-axis from the first portion 31. In other words, the second portion 32 is located in the negative direction of the Y-axis relative to the first portion 31. The second portion 32 includes the first edge 21c, the rest of the third edge 21e, and the rest of the fourth edge 21f of the first substrate 21.

As described above, the first portion 31 and the second portion 32 are the two portions of the first substrate 31 which is divided in the Y-axis direction. Consequently, the first portion 31 and the second portion 32 each include part of the first mounting surface 21a and part of the second mounting surface 21b. The negative direction of the Y-axis is a longitudinal direction in which the first substrate 21 extends, and a direction along the first mounting surface 21a and the second mounting surface 21b.

Plural terminals 35 are disposed on the first portion 31. The terminals 35 are formed by, for example, gold-plating and used for the connection interface 6. Therefore, the first portion 31 forms a connector of the SSD 10. The plural terminals 35 are disposed on, for example, the first mounting surface 21a and arranged in-line along the second edge 21d in the X-axis direction.

The plural electronic components C including the flash memory chips 11, the controller 12, the DRAM 13, the power supply circuit 14, the LED 15, and the temperature sensor are mounted on the second portion 32 of the first substrate 21. Some of the electronic components C may be disposed on the first portion 31.

The plural flash memory chips 11 are disposed in-line in the Y-axis direction. The controller 12 is located in the positive direction of the Y-axis relative to the flash memory chips 11. In other words, the controller 12 is closer to the first portion 31 and the terminals 35 than the flash memory chips 11.

The DRAM 13 and the temperature sensor 16 are disposed in the vicinity of the controller 12. The DRAM 13 and the temperature sensor 16 are located, for example, in the positive direction of the Y-axis relative to the controller 12 and are closer to the first portion 31 and the terminals 35 than the controller.

It is noted that the arrangement of the plural electronic components C is not limited to these examples.

The encapsulating member 22 is known as a mold resin, and is made of, for example, a synthetic resin including an epoxy resin mixed with an inorganic substance such as silicon dioxide. The encapsulating member 22 includes, for example, alumina to improve thermal conductivity. It is noted that the encapsulating member 22 is not limited to this example but may be made of other kinds of synthetic resin and ceramic.

The encapsulating member 22 encapsulates the second portion 32 of the first substrate 21 and the plural electronic components C. In other words, the second portion 32 and the plural electronic components C are covered with the encapsulating member 22. The electronic components C and part of each of the first mounting surface 21a, the second mounting surface 21b, the first edge 21c, the third edge 21e, and the fourth edge 21f of the second portion 32 are covered with the encapsulating member 22.

The encapsulating member 22 is produced by, for example, injection molding. Specifically, the encapsulating member 22 is produced by filling the synthetic resin between a die, and the second portion 32 and the plural electronic components C. This facilitates production of the encapsulating member 22.

It is noted that the making of the encapsulating member 22 is not limited to this example but may be produced by other methods. For example, the encapsulating member 22 may be produced by melting and curing a film of the synthetic resin attached to the second portion 32 and the plural electronic components C. Alternatively, the encapsulating member 22 may be produced by closely adhering a film of the synthetic resin to the second portion 32 and the plural electronic components C by blow molding. Alternatively, the encapsulating member 22 may be produced by curing the synthetic resin applied on the second portion 32 and the plural electronic components C.

The encapsulating member 22 has an outer wall 22a. The encapsulating member 22, or the encapsulating member 22 and at least one component having a higher thermal conductivity than the encapsulating member 22 is filled between the outer wall 22a, and the second portion 32 and the plural electronic components C. In other words, space between the outer wall 22a, and the second portion 32 and the plural electronic components C is solidly filled up with the encapsulating member 22 and the at least one component so that no hollow is formed therein. It is noted that air bubbles generated in the production process or a gap may exist between the outer wall 22a, and the second portion 32 and the plural electronic components C. As another possible embodiment, space may exist between the outer wall 22a, and the second portion 32 and the plural electronic components C.

In this embodiment, as illustrated in FIG. 4, the space between the controller 12 and the outer wall 22a is filled up with the encapsulating member 22 and a heat sink 37. The heat sink 37 is an example of the at least one component. The heat sink 37 is made of metal and has a higher thermal conductivity than the encapsulating member 22. The heat sink 37 is attached to the controller 12 and is thermal contact with the controller 12. Alternatively, the SSD 10 may include the heat sink 37 attached to other electronic components C such as the flash memory chip 11. The controller 12 and the heat sink 37 are in thermal contact with the encapsulating member 22. It is noted that the heat sink 37 may be omitted, and that the space between the controller 12 and the outer wall 22a may be filled up with only the encapsulating member 22.

The encapsulating member 22 has electrically insulative and liquid-proof properties. This enables the encapsulating member 22 to protect, for example, the electronic components C, pads, and wiring disposed on the second portion 32 of the first substrate 21 from an electrically conductive liquid such as water, and dust.

The first portion 31 of the first substrate 21 is not covered with the encapsulating member 22 but exposed. In other words, the first portion 31 is outside of the encapsulating member 22. Consequently, as illustrated in FIG. 2, a connector 41 is detachably connected to the first portion 31.

The SSD 10 is connected to a second substrate 43 with the connector 41 and a cable 42. For example, the connector 41 and the cable 42 are included in the connection interface 6, and the second substrate 43 is included in the host 5. The second substrate 43 is, for example, the motherboard of the host 5. Alternatively, the second substrate 43 may be other substrates such as a relay board.

As illustrated in FIG. 3, the encapsulating member 22 includes an elongated portion 51 and a protrusion 52. The elongated portion 51 may also be referred to as, for example, an insert, an immersed portion or a cooled portion. The protrusion 52 may also be referred to as, for example, a flange or a handle.

The elongated portion 51 encapsulates the second portion 32 and the plural electronic components C and extends in the negative direction of the Y-axis from the protrusion 52. The elongated portion 51 includes a first encapsulating portion 55 and a second encapsulating portion 56. The first encapsulating portion 55 and the second encapsulating portion 56 are arranged in-line in the negative direction of the Y-axis. The second encapsulating portion 56 extends in the negative direction of the Y-axis from the first encapsulating portion 55 and is located in the negative direction of the Y-axis relative to the first encapsulating portion 55.

The first encapsulating portion 55 has a substantially columnar shape along a center axis Ax. The center axis Ax extends in the Y-axis direction. The first encapsulating portion 55 includes a first outer-circumferential wall 55a, a second outer-circumferential wall 55b, and a connection surface 55c. The first outer-circumferential wall 55a, the second outer-circumferential wall 55b, and the connection surface 55c are included in the outer wall 22a of the encapsulating member 22.

The first outer-circumferential wall 55a and the second outer-circumferential wall 55b have a substantially hollow cylindrical shape about the center axis Ax. The second outer-circumferential wall 55b is located in the negative direction of the Y-axis relative to the first outer-circumferential wall 55a. The second outer-circumferential wall 55b has a diameter smaller than the first outer-circumferential wall 55a. The connection surface 55c has a substantially frustoconical shape and connects an end of the first outer-circumferential wall 55a in the negative direction of the Y-axis to an end of the second outer-circumferential wall 55b in the positive direction of the Y-axis. In the Y-axis direction, the second outer-circumferential wall 55b is located between the first outer-circumferential wall 55a and the second encapsulating portion 56.

The second outer-circumferential wall 55b includes an external threaded portion 61 about the center axis Ax. The external threaded portion 61 is an example of a threaded portion. The external threaded portion 61 is a screw thread spirally around the center axis Ax. Alternatively, the threaded portion may be an internal screw thread.

The second encapsulating portion 56 has a substantially rectangular plate shape along the second portion 32. Alternatively, the second encapsulating portion 56 may have other shapes such as a substantially columnar shape. The flash memory chips 11 and the controller 12 are encapsulated by the second encapsulating portion 56. It is noted that part of the controller 12, for example, may be encapsulated by the first encapsulating portion 55.

The distance between the outer wall 22a of the first encapsulating portion 55 and the first substrate 21 is longer than the distance between the outer wall 22a of the second encapsulating portion 56 and the first substrate 21. In other words, the encapsulating member 22 in the second encapsulating portion 56 is thinner than the encapsulating member 22 in the first encapsulating portion 55. As illustrated in FIG. 4, the distance between the heat sink and the outer wall 22a is shorter than the distance between the flash memory chip 11 and the outer wall 22a.

The outer wall 22a of the second encapsulating portion 56 is formed to be substantially flat. Alternatively, the outer wall 22a of the second encapsulating portion 56 may be uneven along the second portion 32 and the plural electronic components C. In the present embodiment, the distance from the second portion 32 to the outer wall 22a of the second encapsulating portion 56 and the distance from the electronic components C to the outer wall 22a of the second encapsulating portion 56 are substantially same.

The protrusion 52 protrudes in a direction orthogonal to the Y-axis direction from an end of the elongated portion 51 in the positive direction of the Y-axis. The protrusion 52 has a disk shape. In other words, the protrusion 52 includes a disk-shaped portion. Alternatively, the protrusion 52 may have other shape portions. The disk-shaped protrusion 52 is concentric with the first outer-circumferential wall 55a, the second outer-circumferential wall 55b, and the external threaded portion 61.

The protrusion 52 has an outer-circumferential wall 52a, a first flat surface 52b, and a second flat surface 52c.

The outer-circumferential wall 52a has a hollow cylindrical shape about the center axis Ax. That is, the outer-circumferential wall 52a is concentric with the first outer-circumferential wall 55a, the second outer-circumferential wall 55b, and the external threaded portion 61. The first flat surface 52b is substantially flat and faces the negative direction of the Y-axis. The first flat surface 52b is connected with an end of the first outer-circumferential wall 55a in the positive direction of the Y-axis. The second flat surface 52c is on an opposite side of the first flat surface 52b and substantially flat, and faces the positive direction of the Y-axis. The second flat surface 52c forms an end of the encapsulating member 22 in the positive direction of the Y-axis. The first portion 31 of the first substrate 21 protrudes from the second flat surface 52c.

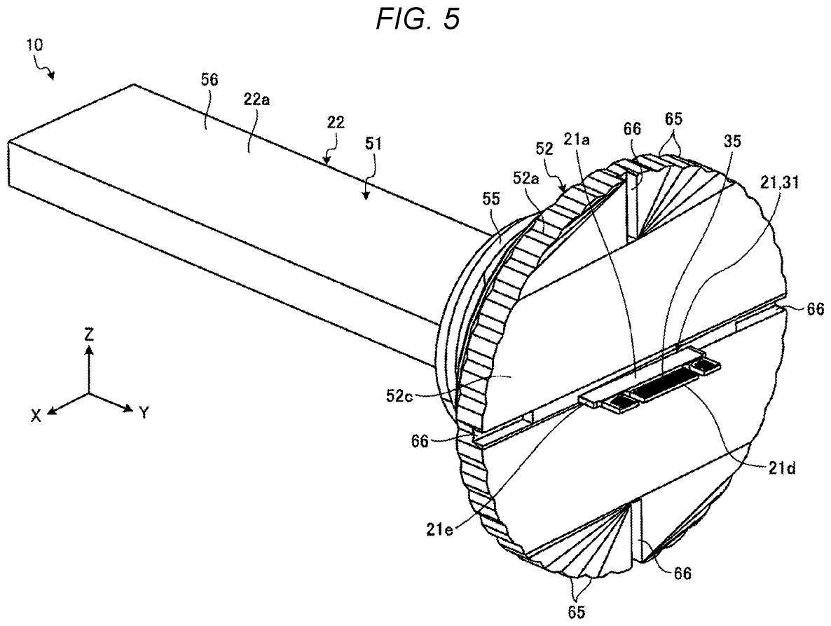

FIG. 5 is a perspective view of the SSD 10 according to the first embodiment, schematically illustrating a configuration of the SSD 10. As illustrated in FIG. 5, the outer-circumferential wall 52a includes plural convex portions 65 and plural concave portions 66. The plural convex portions 65 protrude outward in a radial direction of the center axis Ax from the outer-circumferential wall 52a and are arranged at substantially regular intervals about the center axis Ax. The plural concave portions 66 are notches recessed toward the center axis Ax from the outer-circumferential wall 52a. The concave portions 66 are also recessed from the second flat surface 52c. The plural concave portions 66 are arranged at substantially regular intervals about the center axis Ax.

As illustrated in FIG. 3, the gasket 23 is an O-ring made of, for example, ethylenepropylene rubber (EPDM) coated with silicon, or silicone rubber (VMQ). It is noted that the gasket 23 may be made of other materials. The gasket 23 is attached to the encapsulating member 22. In this embodiment, the gasket 23 is attached to the first outer-circumferential wall 55a of the first encapsulating portion 55.

The gasket 23 is in contact with the first outer-circumferential wall 55a and the first flat surface 52b of the protrusion 52. In other words, the gasket 23 is supported by the first flat surface 52b in the Y-axis direction. At least one of the plural electronic components C is located in the negative direction of the Y-axis relative to the gasket 23. In this embodiment, the flash memory chips 11 and the controller 12 are located away from the gasket 23 in the negative direction of the Y-axis.

As illustrated in FIG. 2, the server system 1 further includes a cooling system 70. The cooling system 70 includes a coolant tank 71, a compressor 72, a heat exchanger 73, and a pipe 74. The coolant tank 71 is an example of a tank.

The coolant tank 71 has, for example, a box shape and includes a bottom wall 81, plural side walls 82, and an upper wall 83. The bottom wall 81, the side walls 82, and the upper wall 83 are an example of walls. The bottom wall 81 and the upper wall 83 have substantially quadrilateral plate shapes over the X-Z plane. The bottom wall 81 is apart from the upper wall 83 in the direction of the Y-axis. The side walls 82 connect the bottom wall 81 to the upper wall 83.

The coolant tank 71 includes a passage 85, a coolant inlet 86, a coolant outlet 87, and a plurality of fastening holes 88. The passage 85 is an example of a space. The fastening holes 88 are an example of holes. The passage 85 is in the coolant tank 71 and enclosed by the bottom wall 81, the side walls 82, and the upper wall 83.

The passage 85 contains coolant 91. The coolant 91 is an example of liquid. The coolant 91 is, for example, water that is mixed with additives and adjusted in melting point and boiling point. The coolant 91 may have electrical conductivity. It is noted that the coolant 91 is not limited to this example.

The coolant inlet 86 and the coolant outlet 87 are formed in the side walls 82 and connect the passage 85 to the outside of the coolant tank 71. The coolant inlet 86 and the coolant outlet 87 may be formed in the same side wall 82 or in different side walls 82. In this embodiment, the coolant inlet 86 is apart from the coolant outlet 87 in the positive direction of the Y-axis.

The coolant inlet 86 and the coolant outlet 87 are connected to each other with the pipe 74 outside of the coolant tank 71. With the pipe 74, the compressor 72 sends the coolant 91 from the coolant outlet 87 to the coolant inlet 86, and the heat exchanger 73 cools the coolant 91.

The fastening holes 88 are formed in the upper wall 83 and connect the passage 85 to the outside of the coolant tank 71. The SSD 10 is fitted into each of the fastening holes 88 to cause the encapsulating member 22 to be immersed in the coolant 91. As illustrated in FIG. 3, the upper wall has a first inner-circumferential surface 83a that defines the fastening hole 88, a second inner-circumferential surface 83b, a third inner-circumferential surface 83c, a first support surface 83d, and a second support surface 83e.

The first inner-circumferential surface 83a, the second inner-circumferential surface 83b, and the third inner-circumferential surface 83c define a substantially hollow cylindrical shapes about the center axis Ax and face the center axis Ax. In the Y-axis direction, the second inner-circumferential surface 83b is located between the first inner-circumferential surface 83a and the third inner-circumferential surface 83c. The second inner-circumferential surface 83b has a diameter smaller than the first inner-circumferential surface 83a and larger than the third inner-circumferential surface 83c.

The first support surface 83d and the second support surface 83e are substantially flat surfaces facing the positive direction of the Y-axis. The first support surface 83d connects an end of the first inner-circumferential surface 83a in the negative direction of the Y-axis with an end of the second inner-circumferential surface 83b in the positive direction of the Y-axis. The second support surface 83e connects an end of the second inner-circumferential surface 83b in the negative direction of the Y-axis with an end of the third inner-circumferential surface 83c in the positive direction of the Y-axis.

When the SSD 10 is fitted in the fastening hole 88, the first support surface 83d faces the first flat surface 52b of the protrusion 52 with space defined therebetween. The gasket 23 is compressed between the first support surface 83d and the first flat surface 52b to seal the space between the first support surface 83d and the first flat surface 52b in a liquid-tight manner.

The third inner-circumferential surface 83c has an internal threaded portion 95 about the center axis Ax. The internal threaded portion 95 is a screw thread spirally around the center axis Ax. The internal threaded portion 95 engages with the external threaded portion 61.

When the SSD 10 operates, the flash memory chips 11 and the controller 12 generate heat. In some cases, the controller 12 generates more heat than the flash memory chips 11. The heat generated by the controller 12 is conducted to the heat sink 37 and the encapsulating member 22. The heat generated by the flash memory chips 11 is conducted to the encapsulating member 22.

The outer wall 22a of the encapsulating member 22 is in contact with the coolant 91. This causes the heat generated by the flash memory chips 11 and the controller 12 to be conducted from the encapsulating member 22 to the coolant 91. The coolant 91 is circulated by the compressor 72 and cooled by the heat exchanger 73. Consequently, the SSD 10 is liquid-cooled by the cooling system 70.

Although the encapsulating member 22 is in direct contact with the coolant 91, the encapsulating member 22 encapsulates the second portion 32 and the plural electronic components C. Thus, the encapsulating member 22 protects the second portion 32 and the plural electronic components C from the coolant 91.

As illustrated in FIG. 2, the plural SSDs 10 are arranged at substantially regular intervals in the X-axis direction. That is, the plural SSDs 10 are arranged in a direction along the first mounting surface 21a and the second mounting surface 21b. The plural SSD 10 may be arranged in two or more rows. In the passage 85, the coolant 91 flows substantially in the X-axis direction.

As illustrated in FIG. 3, in the fastening hole 88, the external threaded portion 61 of the encapsulating member 22 and the internal threaded portion 95 of the upper wall 83 engage with each other. The gasket 23 seals the space between the first flat surface 52b of the encapsulating member 22 and the first support surface 83d of the upper wall 83 in a liquid-tight manner. This prevents the coolant 91 from leaking through the space between the SSD 10 and the upper wall 83. Because the first portion 31 is outside of the coolant tank 71, the coolant 91 is prevented from reaching the terminals 35 and the connector 41.

The gasket 23 when compressed causes reaction force to prevent engagement of the external threaded portion 61 and the internal threaded portion 95 from loosening. Alternatively, a screw locking adhesive may be used to prevent engagement of the external threaded portion 61 and the internal threaded portion 95 from loosening.

When the SSD 10 is fitted into the fastening hole 88, the second encapsulating portion 56 is first inserted into the fastening hole 88 in the negative direction of the Y-axis (i.e., downward) from the outside of the coolant tank 71. Next, the SSD 10 is rotated about the center axis Ax to make the external threaded portion 61 and the internal threaded portion 95 engage with each other, and the SSD 10 moves in the negative direction of the Y-axis.

The protrusion 52 has a larger diameter than the elongated portion 51. The operator grips the protrusion 52 to rotate the SSD 10 with less torque. The plurality of convex portions 65 function as a slip stopper.

A tool is fittable in the concave portions 66 of the protrusion 52. With this tool, more torque is applied to the SSD 10 to facilitate rotation of the SSD 10. The concave portions 66 have dimples at the bottom to prevent the tool from damaging the gasket 23.

In accordance with the rotation, the SSD 10 moves in the negative direction of the Y-axis to make the gasket 23 come into contact with the first support surface 83d. When the SSD 10 further moves, the gasket 23 is compressed between the first support surface 83d and the first flat surface 52b to seal the space between the first support surface 83d and the first flat surface 52b in a liquid-tight manner. In the above-described manner, the SSD 10 is fitted in and fastened to the fastening hole 88. The SSD 10 may be inserted in the fastening hole 88 after the passage 85 is filled with the coolant 91.

In the server system 1 according to the first embodiment described so far, each of the first substrates 21 includes the first portion 31 and the second portion 32 arranged in-line in the negative direction of the Y-axis, which is the longitudinal direction of the first substrate 21, and the terminals 35 are disposed on the first portion 31. The encapsulating member 22 encapsulates the second portion 32 and the plural electronic components C mounted on the second portion 32. With this configuration, even when part of the SSD 10 encapsulated by the encapsulating member 22 is immersed in the electrically conductive coolant 91, the encapsulating member 22 protects the electronic components C and the second portion 32 of the first substrate 21 to prevent occurrence of a short circuit. This makes it possible to liquid-cool the SSD 10 by the electrically conductive coolant 91 to prevent heat from degrading the reliability of the SSD 10. Encapsulation of the electronic components C by the encapsulating member 22 enables the encapsulating member 22 and the electronic components C, both of which are solid, to conduct heat to each other to effectively cool the electronic components C. The encapsulating member 22 facilitates liquid-cooling described above and thus an increase in cost of the SSD 10 is reduced.

Encapsulation of the plural electronic components C by the encapsulating member 22 increases efficiency of heat exchange between the coolant 91 and the controller 12 in comparison with covering the SSD 10 with a film and a case. Encapsulation of the plural electronic components C by the encapsulating member 22 also prevents the electronic components C from falling off the first substrate 21. This improves security of the SSD 10.

The space between the controller 12 and the outer wall 22a is filled up with the encapsulating member 22, or the encapsulating member 22 and the heat sink 37. With this configuration, heat generated by the controller 12 is conducted to the outer wall 22a through the encapsulating member 22, or the encapsulating member 22 and the heat sink 37. This, for example, improves efficiency of heat exchange between the coolant 91 in contact with the outer wall 22a, and the controller 12 to prevent heat from degrading the reliability of the controller 12.

The first portion 31 is located outside of the encapsulating member 22. This makes the connector 41 connectable to the terminals 35 disposed on the first portion 31. Consequently, with the second portion 32 and the plural electronic components C encapsulated by the encapsulating member 22, the SSD 10 can receive power supply and perform data transmission and reception through the terminals 35.

The gasket 23 can seal, for example, the space between the upper wall 83 to which the SSD 10 is fastened, and the SSD 10 in a liquid-tight manner. At least one of the plural electronic components C is located in the negative direction of the Y-axis relative to the gasket 23. In order to cool the electronic components C, the portion of the encapsulating member 22 which is located in the negative direction of the Y-axis relative to the gasket 23 is immersed in the coolant 91. The first portion 31 on which the terminals 35 are disposed is located in the positive direction of the Y-axis relative to the second portion 32 on which the electronic components C are mounted. Thus, the gasket 23 can prevent the coolant 91 from reaching the terminals 35.

The encapsulating member 22 includes the elongated portion 51, which extends in the negative direction of the Y-axis and encapsulates the second portion 32 and the plural electronic components C, and the protrusion 52 protruding from the elongated portion 51 in the direction orthogonal to the negative direction of the Y-axis. The gasket 23 is supported by the protrusion 52. With this configuration, when the SSD 10 is inserted into the fastening hole 88 in the negative direction of the Y-axis, the gasket 23 is compressed between the protrusion 52 and the upper wall 83 to seal the space between the upper wall 83 and the SSD 10 in a liquid-tight manner.

The distance between the outer wall 22a of the first encapsulating portion 55 and the first substrate 21 is longer than the distance between the outer wall 22a of the second encapsulating portion 56 and the first substrate 21. That is, the second encapsulating portion 56 is thinner than the first encapsulating portion 55. The controller 12 is encapsulated by the second encapsulating portion 56. This improves efficiency of heat exchange between the controller 12 and the coolant 91 in contact with the outer wall 22a, which enables to prevent heat from degrading reliability of the controller 12.

The first encapsulating portion 55 includes the external threaded portion 61 about the center axis Ax extending in the negative direction of the Y-axis. With this configuration, when the external threaded portion 61 is screwed into the fastening hole 88, which is a screw hole, the gasket 23 is compressed between the protrusion 52 and the upper wall 83 to seal the space between the upper wall 83 and the SSD 10 in a liquid-tight manner. The external threaded portion 61 fitted in the internal threaded portion 95 can also fill up the space between the upper wall 83 and the SSD 10.

The protrusion 52 includes the disk-shaped portion concentric with the external threaded portion 61. The protrusion 52 protrudes in the direction orthogonal to the negative direction of the Y-axis from the elongated portion 51. Consequently, the diameter of the protrusion 52 is larger than the diameter of the elongated portion 51. With this configuration, the operator grips and rotates the protrusion 52 to easily screw the external threaded portion 61 into the fastening hole 88.

The protrusion 52 has the outer-circumferential wall 52a concentric with the external threaded portion 61, and the concave portions 66 are recessed toward the center axis Ax of the external threaded portion 61 from the outer-circumferential wall 52a. With this configuration, a tool, for example, is fitted in the concave portions 66 to apply large torque to the protrusion 52 with the tool to easily screw the external threaded portion 61 into the fastening hole 88.

The coolant tank 71 includes the bottom wall 81, the side walls 82, the upper wall 83, the passage 85, which may contain the coolant 91, and the fastening holes 88 in the upper wall 83 to connect the passage 85 to the outside of the coolant tank 71. The SSD 10 is screwed into each of the fastening holes 88 to cause the encapsulating member 22 to be immersed in the coolant 91. With this configuration, the SSD 10 can be liquid-cooled by the coolant 91 to prevent heat from degrading the reliability of the SSD 10.

The plural SSDs 10 are immersed in the coolant 91 in the passage 85. Consequently, there is no need to provide the cooling system 70 for each of the SSDs, thus reducing an increase in cost of the server system 1.

The SSD 10 is detachably fitted into and fastened to the fastening hole 88 in the upper wall 83 by screwing, for example. This configuration facilitates replacement of the SSD 10 in case of a malfunction, for example.

### Second Embodiment

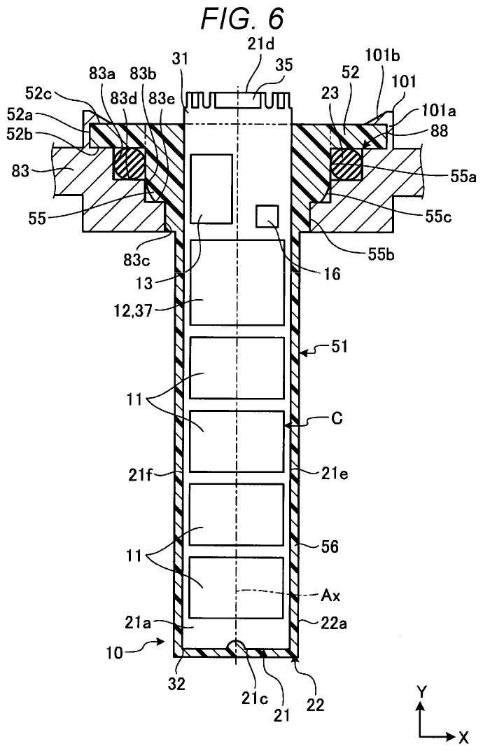

A second embodiment will be described below with reference to FIG. 6. In the following description of second and other embodiments, components that have the same functions as the components in the above description are denoted with identical reference numerals and signs. Plural components denoted with identical reference numerals and signs do not necessarily have all functions and properties in common and may have functions and properties that vary in accordance with each of the embodiments.

FIG. 6 is a cross-sectional view of the SSD 10 according to the second embodiment, schematically illustrating a configuration of the SSD 10. As illustrated in FIG. 6, the coolant tank 71 in the second embodiment includes plural elastic engagement portions 101 instead of the internal threaded portions 95. In the SSDs 10 in the second embodiment, the external threaded portions 61 are omitted.

Each of the elastic engagement portions 101 includes a flexible portion 101a and a tapered rim 101b. The flexible portion 101a extends in the positive direction of the Y-axis from the upper wall 83 along the outer-circumferential wall 52a of the protrusion 52. The tapered rim 101b extends toward the center axis Ax from an end of the flexible portion 101a in the positive direction of the Y-axis. In the Y-axis direction, the protrusion 52 is held between the tapered rim 101b and the upper wall 83.

The tapered rim 101b presses the second flat surface 52c of the protrusion 52 in the negative direction of the Y-axis. This causes the gasket 23 to be compressed between the first flat surface 52b of the protrusion 52 and the first support surface 83d of the upper wall 83 to seal the space between the first flat surface 52b and the first support surface 83d in a liquid-tight manner.

The elastic engagement portion 101 installs the SSD 10 by snap-fitting. When the SSD 10 is fitted into the fastening hole 88, the second encapsulating portion 56 is first inserted in the fastening hole 88 from the outside of the coolant tank 71. The tapered rim 101b comes into contact with the protrusion 52 to limit further movement of the SSD 10 in the negative direction of the Y-axis.

Next, the flexible portion 101a is elastically deformed to make the tapered rim 101b move away from the protrusion 52 and allow the SSD 10 to further move in the negative direction of the Y-axis. When the protrusion 52 passes by the tapered rim 101b, elastic deformation of the flexible portion 101a is stopped to allow the tapered rim 101b to come into contact with the second flat surface 52c of the protrusion 52.

The tapered rim 101b presses the protrusion 52 to cause the gasket 23 to be compressed between the first support surface 83d and the first flat surface 52b to seal the space between the first support surface 83d and the first flat surface 52b in a liquid-tight manner. In this manner, the SSD 10 in the second embodiment is fitted in the fastening hole 88 and fastened to the upper wall 83.

### Third Embodiment

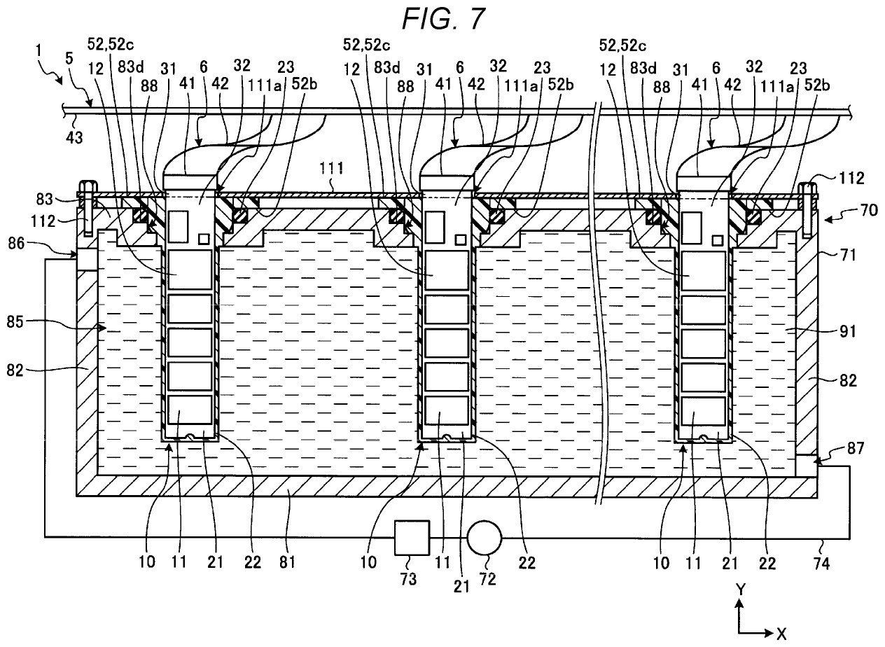

A third embodiment will be described below with reference to FIG. 7. FIG. 7 is a cross-sectional view of part of the server system 1 according to the third embodiment, schematically illustrating a configuration of the part. As illustrated in FIG. 7, the cooling system 70 in the third embodiment includes a holding plate 111 and plural screws 112. In the third embodiment, the external threaded portions 61 of the SSDs 10 and the internal threaded portions 95 of the upper wall 83 are omitted.

The holding plate 111 is a substantially flat plate extending over the X-Z plane. The holding plate 111 includes plural insertion holes 111a. The first portion 31 extends through each of the insertion holes 111a and protrudes from the holding plate 111. The holding plate 111 is supported by the second flat surface 52c of the protrusion 52.

The screws 112 fasten the holding plate 111 on the coolant tank 71. In the Y-axis direction, the protrusion 52 is held between the holding plate 111 and the upper wall 83. The holding plate 111 presses the second flat surface 52c of the protrusion 52 in the negative direction of the Y-axis. Thus, the gasket 23 is compressed between the first flat surface 52b of the protrusion 52 and the first support surface 83d of the first wall 83 to seal the space between the first flat surface 52b and the first support surface 83d in a liquid-tight manner. In this manner, the SSD 10 in the third embodiment is fitted in the fastening hole 88 and fastened to the upper wall 83.

In the above-described plural embodiments, the first portion 31 of the first substrate 21 is located outside of the encapsulating member 22. Alternatively, the encapsulating member 22 may further encapsulate the first portion 31. In this case, for example, power is supplied to the SSD 10 by wireless power supply, and data is transmitted and received between the SSD 10 and the host 5 by wireless communication.

According to at least one of the embodiments described above, the substrate includes the first portion and the second portion arranged in-line in the first direction, which is the longitudinal direction of the substrate, with the terminals disposed on the first portion. The encapsulating member encapsulates the second portion and the plural electronic components mounted on the second portion. With this configuration, even when part of the memory system encapsulated by the encapsulating member is immersed in electrically conductive liquid, the encapsulating member protects the electronic components and the second portion of the substrate so as to prevent a short circuit. This ensures liquid cooling of the memory system using electrically conductive liquid to prevent heat from degrading the reliability of the memory system. Encapsulation of the electronic components with the encapsulating member makes possible thermal conduction between the encapsulating member and the electronic components, both of which are solid, to effectively cool the electronic components. The encapsulating member facilities the liquid cooling to reduce an increase in cost of the memory system.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system comprising:
a substrate extending in a first direction and including first and second portions that are arranged along a line in the first direction;
terminals disposed on the first portion;
electronic components mounted on the second portion and including a nonvolatile memory and a controller configured to control the nonvolatile memory; and
an encapsulating member that encapsulates the second portion and the electronic components.

2. The memory system according to claim 1,
wherein the encapsulating member comprises an outer wall and an inner filler portion that fills a space between the controller and the outer wall.

3. The memory system according to claim 1, further comprising:
a heat sink in thermal contact with the controller,
wherein the encapsulating member comprises an outer wall and an inner filler portion that fills a space between the heat sink and the outer wall.

4. The memory system according to claim 3, further comprising:
a gasket attached to the encapsulating member,
wherein at least one of the electronic components is located between the gasket and a first end of the second portion located away from the first portion in the first direction.

5. The memory system according to claim 4, wherein the encapsulating member comprises:
an elongated portion extending in the first direction and encapsulating the second portion and the electronic components, and
a protrusion at a second end of the elongated portion that is closer to the first portion than the second portion, that protrudes from the elongated portion in a direction orthogonal to the first direction.

6. The memory system according to claim 5, wherein the gasket is disposed on an outer circumferential surface of the protrusion.

7. The memory system according to claim 5, wherein
the elongated portion includes a first encapsulating portion and a second encapsulating portion, a distance between an outer surface of the first encapsulating portion and the substrate being larger than a distance between an outer surface of the second encapsulating portion and the substrate, and
the controller is encapsulated by the second encapsulating portion.

8. The memory system according to claim 7, wherein the first encapsulating portion comprises a threaded portion around an axis extending in the first direction.

9. The memory system according to claim 8, wherein the protrusion comprises a disk-shaped portion that is concentric with the threaded portion.

10. The memory system according to claim 9, wherein the protrusion comprises:
concave portions recessed from an outer circumferential surface of the protrusion toward the center axis of the threaded portion.

11. A storage system comprising:
a tank including walls that form a space for containing liquid and at least one hole formed through one of the walls; and
a memory device having a first part that is inserted into the at least one hole and into the space and a second part that remains outside the space,
wherein the first part includes an electronic component and an encapsulating member that encapsulates the electronic component and the second part includes a connector.

12. The storage system according to claim 11, wherein the encapsulating member comprises:
an elongated portion extending in a first direction into the space and encapsulating the electronic components, and
a head portion that is attached to the tank.

13. The storage system according to claim 12, further comprising a gasket that is fitted between the head portion and the tank.

14. The storage system according to claim 12, wherein the head portion includes a threaded portion that is engaged with a threaded portion of the tank.

15. The storage system according to claim 12, wherein the head portion is pressure-fitted to elastic engagement portions of the tank.

16. The storage system according to claim 12, further comprising a holding plate that attaches the head portion to the tank.

17. The storage system according to claim 12, wherein
the elongated portion includes a first encapsulating portion and a second encapsulating portion, a distance between an outer surface of the first encapsulating portion and a substrate of the memory device being larger than a distance between an outer surface of the second encapsulating portion and the substrate of the memory device, and
the electronic component includes a nonvolatile memory or a memory controller that is encapsulated by the second encapsulating portion.

18. The storage system according to claim 12, wherein the head portion comprises:
concave portions recessed from an outer circumferential surface of the head portion at regular intervals.

19. The storage system according to claim 12, wherein the elongated portion has a rectangular plate shape and the head portion has at least one circular outer circumference.

20. The storage system according to claim 19, further comprising an O-ring around one of the at least one circular outer circumference of the head portion.
